(19) United States
(12) Patent Application Publication
(10) Pub. No.: US 2015/0357203 A1
(43) Pub. Date: Dec. 10, 2015

(54) PATTERNING METHOD AND PATTERNING APPARATUS

(71) Applicant: MACRONIX International Co., Ltd., Hsinchu (TW)

(72) Inventor: Ta-Hone Yang, Hsinchu (TW)

(73) Assignee: MACRONIX International Co., Ltd., Hsinchu (TW)

(21) Appl. No.: 14/296,862

(22) Filed: Jun. 5, 2014

(51) Int. Cl. H01L 21/32; H01L 27/115; H01L 21/266; H01L 21/311; H01L 21/3213

(52) U.S. Cl. CPC H01L 21/32; H01L 21/31116; H01L 21/32136; H01L 21/266; H01L 27/11551; H01L 27/11578

(57) ABSTRACT

A patterning method is described. A patterned mask layer is formed on a material layer, having therein a first opening exposing a portion of the material layer. A pre-treatment process is performed to modify the material layer exposed in the first opening and form a modified region therein. An etching process is performed to remove the material layer in the modified region at least and form a second opening in the material layer.

### BACKGROUND OF THE INVENTION

1. Field of Invention

This invention relates to semiconductor process and processing apparatus, and particularly relates to a patterning method and a patterning apparatus.

2. Description of Related Art

In accompany with increased requirement on high density of memories such as floating-gate memory, charge-trapping memory and embedded memory, etc., the design of memory array has been turned to 3D structures form planar 2D structures to increase the storage capacity in a finite chip area.

In order to achieve a higher storage capacity for a 3D memory array, the number of the stacked layers of memory is unceasingly increased, so the aspect ratio of trenches to be formed by etching is unceasingly increased. However, since the reachable depth of reactive ions in etching processes such as an anisotropic etching process is limited, the etching tends to be incomplete so that a stringer residue is left at the bottom of the etching-formed trench. If the stringer residue is not removed subsequently, the fabricated device will have abnormal electrical connection to cause a short circuit.

### SUMMARY OF THE INVENTION

In view of the foregoing, this invention provides a patterning method and a patterning apparatus, which are capable of making complete etching and preventing a stringer residue of etching.

The patterning method of this invention is described below. A patterned mask layer is formed on a material layer, having therein a first opening exposing a portion of the material layer. A pre-treatment process is performed to modify the material layer exposed in the first opening and form a modified region therein. A first etching process is performed to remove the material layer in the modified region at least and form a second opening in the material layer.

In an embodiment of the method, the pre-treatment process includes an ion implantation process. In such case, the first etching process may include a plasma etching process.

In an embodiment of the method, before the pre-treatment process is performed, a second etching process is performed with the patterned mask layer as a mask to remove a portion of the material layer exposed in the first opening. After the first etching process is performed, regardless of presence or absence of the above second etching process, a third etching process may be performed with the patterned mask layer as a mask to remove a portion of the material layer exposed in the second opening. After the third etching process is performed, it is possible to repeat the pre-treatment process and the first etching process.

The patterning apparatus includes a multi-compartment chamber, an etching unit, a modification unit and a transfer unit. The multi-compartment chamber includes a first compartment and a second compartment at least. The etching unit is in the first compartment and is for etching a material layer. The modification unit is in the second compartment and is for modifying the material layer. The transfer unit is arranged between the first compartment and the second compartment and is for transferring the material layer between the first compartment and the second compartment.

In an embodiment of the patterning apparatus, the modification unit includes an ion implantation machine. The etching unit may include a plasma etching machine.

The patterning method of this invention is capable of making complete etching and preventing problems such as etching residue.

The patterning apparatus of this invention is capable of performing the above modification step and the above etching step to finish the patterning process in the same chamber without breaking the vacuum.

In order to make the aforementioned and other objects, features and advantages of this invention comprehensible, a preferred embodiment accompanied with figures is described in detail below.

### BRIEF DESCRIPTION OF THE DRAWINGS

FIGS. 1A to 1E schematically illustrate, in a cross-sectional view, a patterning method according to an embodiment of this invention.

FIG. 2 illustrates a process flow chart of a patterning method according to a first embodiment of this invention.

FIG. 3 illustrates a process flow chart of a patterning method according to a second embodiment of this invention.

FIG. 4 illustrates a process flow chart of a patterning method according to a third embodiment of this invention.

FIGS. 5A to 5D schematically illustrate, in a cross-sectional view, a patterning method according to another embodiment of this invention.

FIG. 6 schematically illustrates a patterning apparatus according to an embodiment of this invention.

FIG. 7 schematically illustrates a plasma etching machine in the prior art.

FIG. 8 schematically illustrates an ion implantation machine in the prior art.

### DESCRIPTION OF EMBODIMENTS

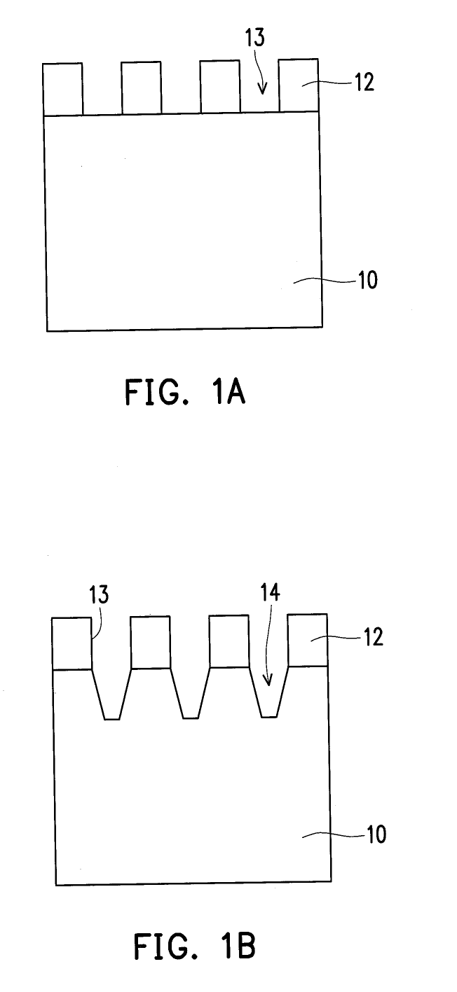

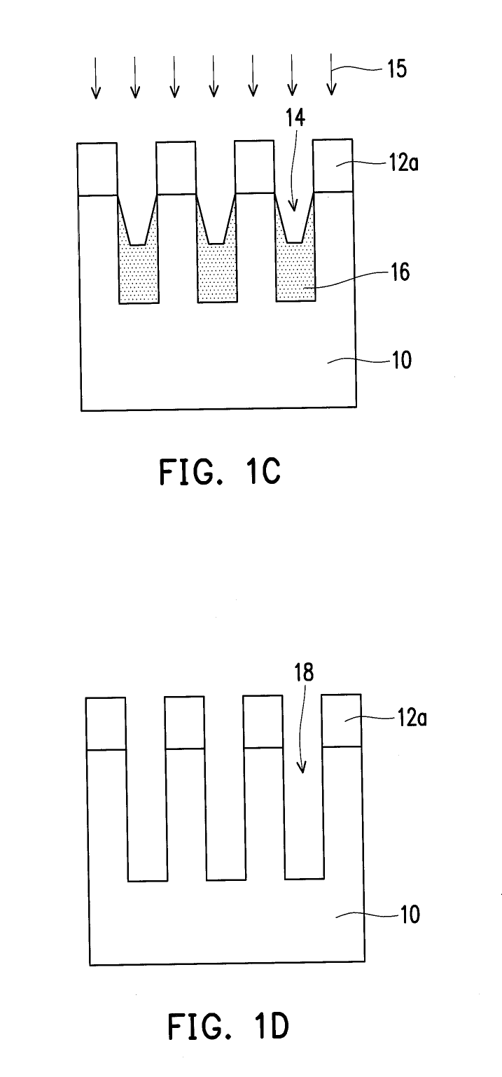

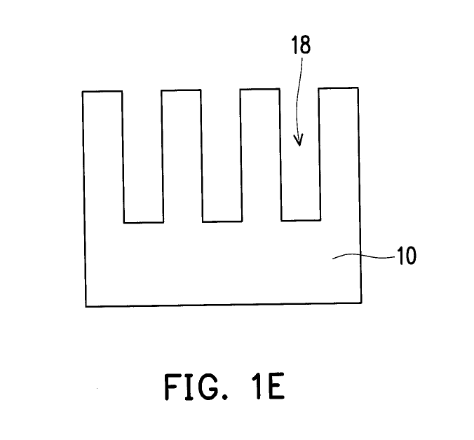

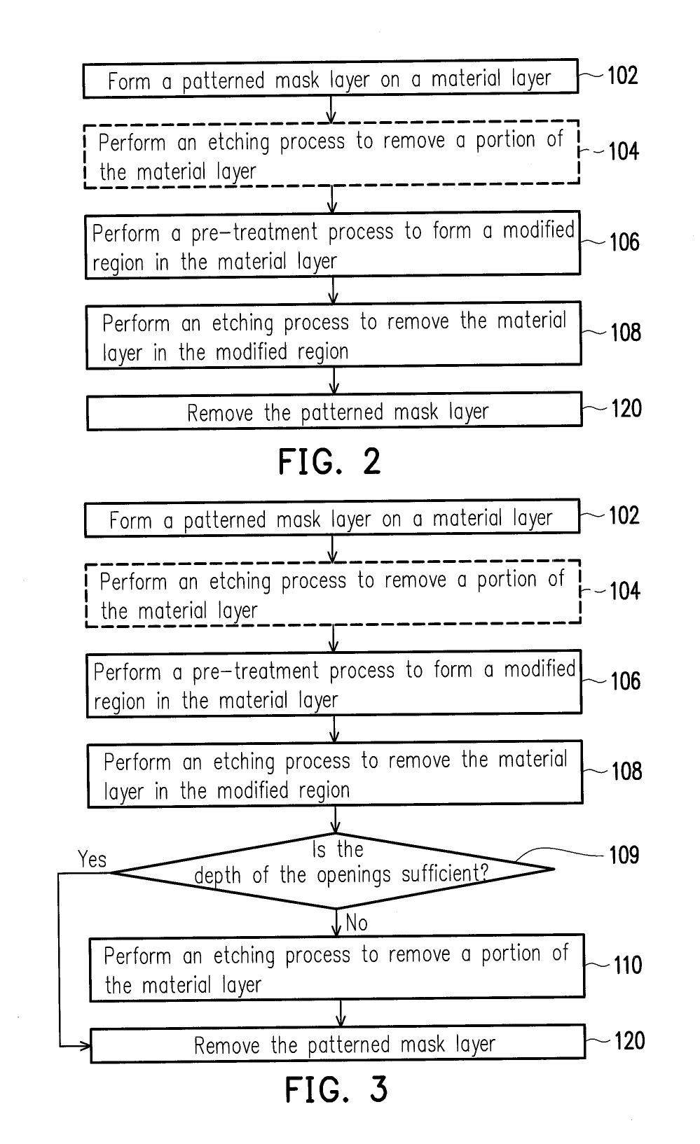

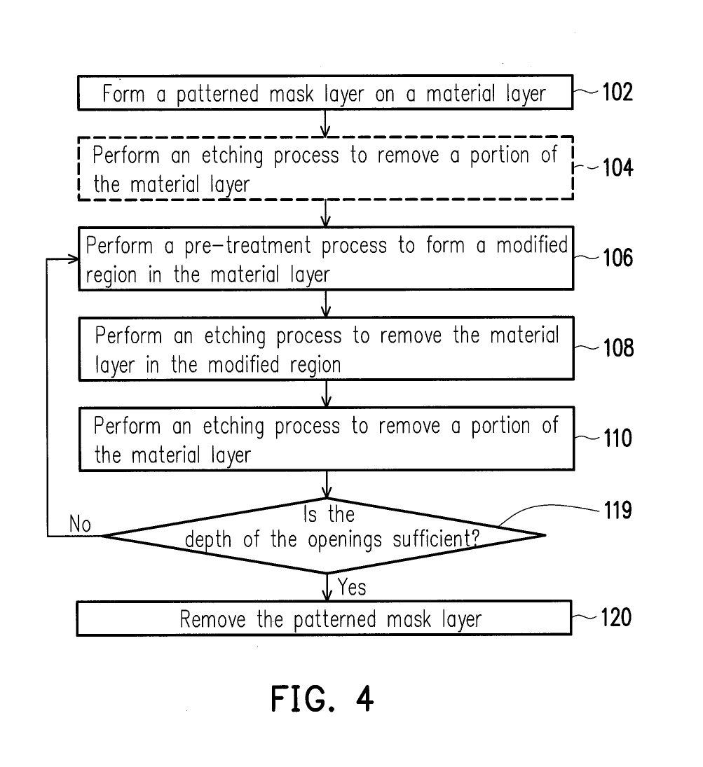

This invention is further explained with the following embodiments, which are not intended to limit the scope thereof. FIGS. 1A to 1E schematically illustrate, in a cross-sectional view, a patterning method according to an embodiment of this invention. FIG. 2 illustrates a process flow chart of a patterning method according to a first embodiment of this invention. FIG. 3 illustrates a process flow chart of a patterning method according to a second embodiment of the same. FIG. 4 illustrates a process flow chart of a patterning method according to a third embodiment of the same.

Referring to FIGS. 1A and 2, in step 102, a patterned mask layer 12 is formed on a material layer 10. The material layer 10 may be composed a single material, or a stacked structure formed by stacking two or more materials. In an embodiment, the material layer 10 includes a semiconductor wafer. The semiconductor wafer may be formed from at least one semiconductor material selected from the group consisting of Si, Ge, SiGe, GaP, GaAs, SiC, SiGeC, InAs and InP. In another embodiment, the material layer 10 includes a silicon-on-insulator (SOI) substrate. In still another embodiment, the material layer 10 includes a stacked structure of silicon oxide layers and poly-Si layers. The patterned mask layer 12 may include a patterned photoresist layer, and has therein openings 13 exposing portions of the material layer 10.

Referring to FIGS. 1B and 2, in step 104, an etching process is performed using the patterned mask layer 12 as a mask to remove a portion of the material layer 10 exposed in each opening 13 and form a recess 14. The sidewall of the recess 14 may be a vertical sidewall parallel to the normal line of the material layer 10, or an inclined sidewall forming a sharp angle with the normal line of the material layer 10. The etching process may be an anisotropic etching process, which is possibly a dry etching process. The dry etching process may be a plasma etching process. In embodiments where the material layer 10 is a silicon layer or a silicon substrate, the reactive gas used in the dry etching process may include Cl₂ and CF₄, and the RF (radiofrequency) power may range from 13.56 MHz to 2.45 GHz.

Referring to FIGS. 1C and 2, in step 106, a pre-treatment process 15 is performed to modify a portion of the material layer 10 and form a modified region 16 in the material layer 10 under the recess 14 and at the sidewall of the recess 14. More specifically, the pre-treatment process 15 may be a treatment capable of destroying the structure (e.g., lattice) of the material layer 10 under the recess 14 and at the sidewall of the recess 14. In an embodiment, the pre-treatment process 15 includes an ion implantation process. The ion implantation process not only is capable of destroying the lattice of the material layer 10 under the recess 14 and at the sidewall of the recess 14, but also is capable of causing crosslinking in the patterned mask layer 12 to form a harder patterned mask layer 12a that increases the etching selectivity of the underlying material layer 10 relative thereto. The ion source of the ion implantation process may be Ar, N₂, P or a combination thereof. The energy of the ion implantation may be within the range of 5 to 60 keV. The angle between the implantation direction and the normal direction of the material layer 10, namely the inclination angle of the ion implantation process, may be within the range of 0 to 7 degrees. The dosage of the ion implantation process may be within the range of 1×10¹⁵/cm² to 5×10¹⁶/cm².

Referring to FIGS. 1D and 2, in step 108, an etching process is performed to remove the material layer 10 in the modified regions 16 at least and form openings 18. In an embodiment, the etching process removes the material layer 10 in the modified regions 16 only. In another embodiment, the etching process further removes a portion of the material layer 10 under the modified regions 16. The etching process may be an anisotropic etching process, which is possibly a dry etching process. The dry etching process may be a plasma etching process, an ion beam etching process, or an electron beam etching process. In embodiments where the material layer 10 is a silicon layer or substrate, the reactive gas used in the dry etching process may include Cl₂ and CF₄, and the RF power may range from 13.56 MHz to 2.45 GHz. Since the structure of the material layer 10 in the modified regions 16 has been destroyed in the pre-treatment process 15, the material layer 10 in the modified regions 16 can be easily removed by the etching process. Moreover, since crosslinking is caused in the patterned mask layer 12 in the pre-treatment process 15 to form a harder patterned mask layer 12a that makes a higher etching selectivity, the mask layer loss in the etching can be reduced.

Referring to FIGS. 1E and 2, in step 120, the etching is terminated if the openings 18 have had a required depth, and the patterned mask layer 12a is removed.

Referring to FIGS. 1E and 3, whether the openings 18 have a sufficient depth is determined in step 109. If the depth of the openings 18 is sufficient, the patterned mask layer 12a is removed in step 120. If the depth of the openings 18 is not sufficient, the etching is continued in step 110 until the openings 18 have a required depth, and then the patterned mask layer 12a is removed in step 120.

Referring to FIGS. 1E and 4, alternatively, after the continued etching process is performed in step 110, whether the openings 18 have a sufficient depth is determined in step 119. If the depth of the openings 18 is sufficient, the patterned mask layer 12a is removed in step 120. If the depth is not sufficient, the pre-treatment process 15 (step 106), the etching process (step 108) and the continued etching process (step 110) are repeated one or more times until the openings 18 in the material layer 10 have a required depth, and then the patterned mask layer 12a is removed (step 120). The openings 18 may be trenches or contact holes in the substrate.

Although in the above embodiments an etching process is performed before the pre-treatment process 15 to remove a portion of the material layer 10 and form a recess 14, the scope of this invention is not limited thereto. In other embodiments, the step 104 described in FIGS. 2 to 4 may be omitted.

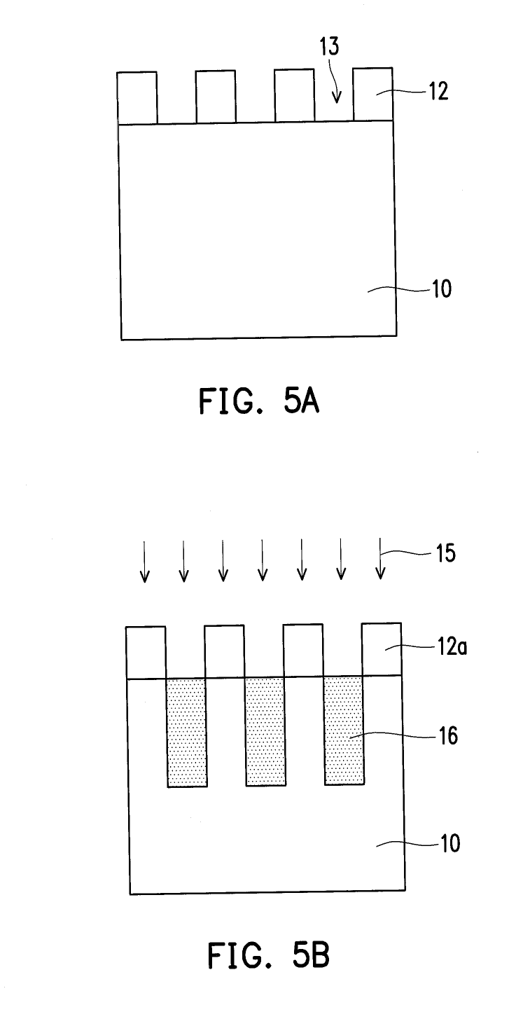

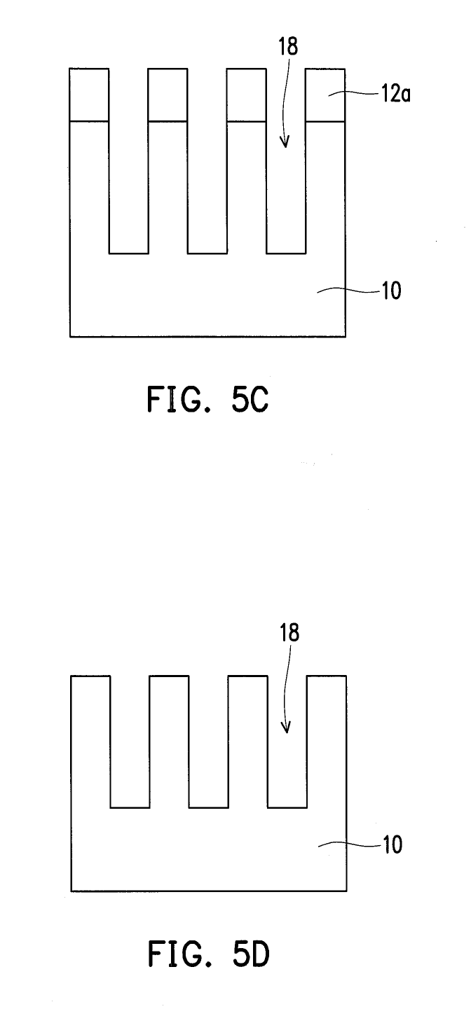

For example, FIGS. 5A to 5D schematically illustrate, in a cross-sectional view, a patterning method according to such an embodiment. Since the process shown in FIGS. 5A to 5D is similar to that shown in FIGS. 1A to 1E, only the differences of the former from the latter are described in details below.

Referring to FIG. 5B, an etching process is not performed before the pre-treatment process 15, so a recess 14 as shown in FIG. 1B is not formed in the material layer 10, and the pre-treatment process 15 is performed to the planar material layer 10 exposed by the patterned mask layer 12. The process shown in FIGS. 5C to 5D is not described here as being similar to that shown in FIGS. 1C to 1E.

In the above patterning methods, the etching process and the pre-treatment process may be performed in different chambers, or be performed in the same chamber without breaking vacuum. This will be explained based on the embodiment described below, but this invention is not limited to the embodiment.

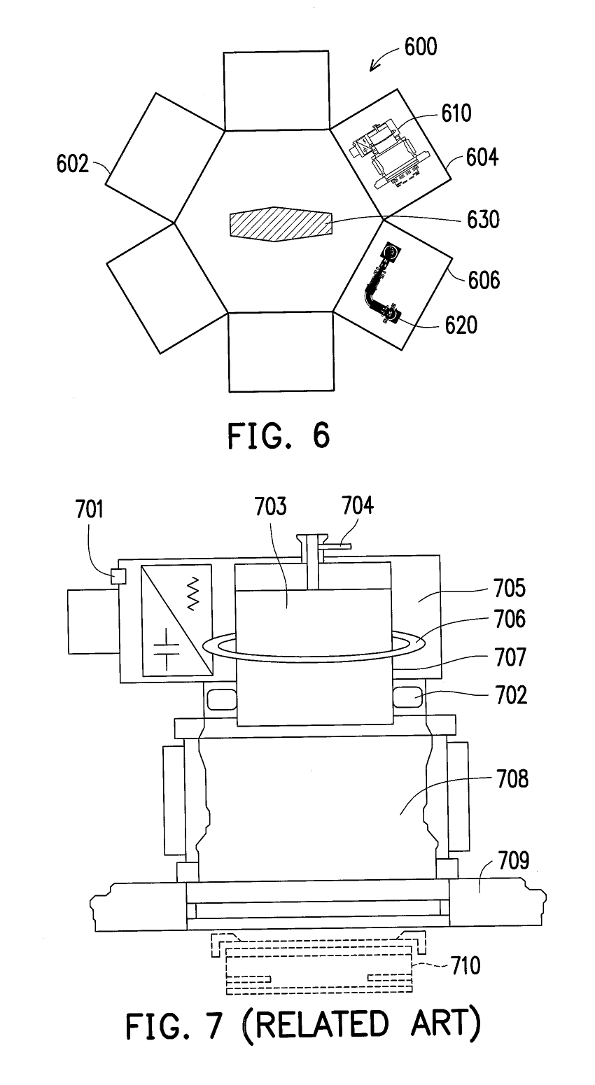

FIG. 6 schematically illustrates a patterning apparatus according to an embodiment of this invention.

Referring to FIG. 6, the patterning apparatus 600 includes a multi-compartment chamber 602, an etching unit 610, a modification unit 620 and a transfer unit 630. The multi-compartment chamber 602 has therein a vacuum environment, including a first compartment 604 and a second compartment 606 at least. The first compartment 604 and the second compartment 606 are both under vacuum, but their vacuum degrees may be different form each other.

The etching unit 610 is in the first compartment 604 and is for etching a material layer. The etching unit 610 may include a plasma etching machine, a wet etching machine, an ion beam etching machine, or an electron beam etching machine.

FIG. 7 schematically illustrates a plasma etching machine in the prior art.

Referring to FIG. 7, the plasma etching machine includes RF power 701, a DC power 702, plasma 703, a process gas inlet 704, an inductively coupling plasma (ICP) source 705, an antenna 706, a dielectric cylinder 707, a diffusion chamber 708, a substrate holder 709, a wafer voltage biasing RF 710, a vacuum system (not shown), and a temperature control unit (not shown).

The modification unit 620 is disposed in the second compartment 606 and is for modifying the material layer, namely destroying the structure (e.g., the lattice) of the material layer. The modification unit 620 may include an ion implantation machine, or an electron beam irradiation machine. The ion implantation machine may include a gas system, a vacuum system, a control system and a beam-line system.

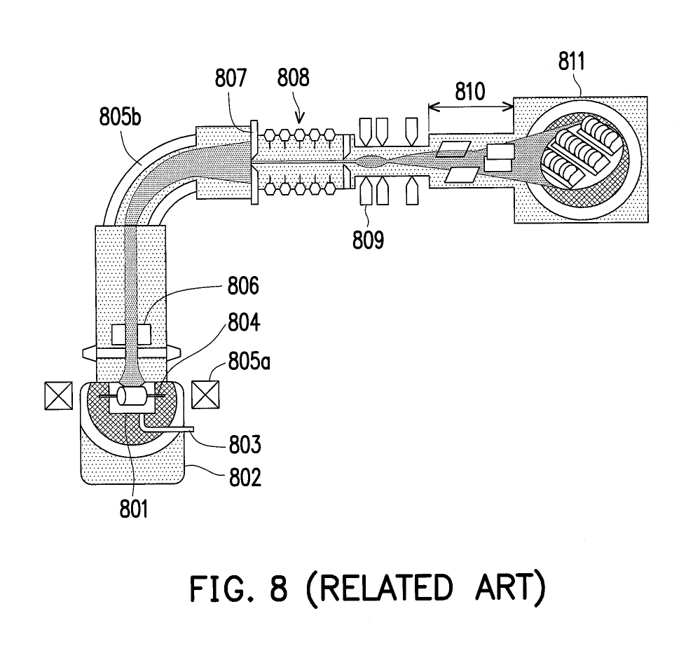

FIG. 8 schematically illustrates an ion implantation machine in the prior art.

Referring to FIG. 8, the ion implantation machine includes a chamber (anode) 801, an ion source 802, an elemental source 803, a filament (cathode) 804, magnets 805a and 805b, an extraction electrode 806, a mass analyzer 807, an ion acceleration column 808, a lens set 809, electronic scanning 810, an end station 811, a gas system (not shown), a vacuum system (not shown), and a control unit (not shown), etc.

The transfer unit 630 is arranged between the first compartment 604 and the second compartment 606, possibly being a central region 608 of the multi-compartment chamber 602. The transfer unit 630 is for transferring the material layer (or wafer) between the etching unit 610 and the modification unit 620. The transfer unit 630 may include a robot that loads and unloads the wafer.

Although each of the above embodiments is described by a system including a single etching unit and a modification unit, this invention is not limited thereto. If required, the patterning apparatus may include plural etching units and plural modification units in more compartments of the multi-compartment chamber.

Accordingly, this invention utilizes the pre-treatment process to modify a portion of the exposed material layer into a modified region having a destroyed structure, so the portion of the material layer can be easily removed in the subsequent etching process. Hence, this invention is very suitable for forming openings with a high aspect ratio, and is capable of preventing problems such as uneasy profile control of openings with a high aspect ratio, and etching residue.

Moreover, the patterning apparatus of this invention may carry out the modification process and the etching process without breaking vacuum, so that the patterning process of this invention can be carried out without breaking vacuum.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

1. A patterning method, comprising:
forming, on a material layer, a patterned mask layer having therein a first opening exposing a portion of the material layer;
performing a pre-treatment process to modify the material layer exposed in the first opening and form a modified region therein; and
performing a first etching process to remove the material layer in the modified region at least and form a second opening in the material layer.

2. The patterning method of claim 1, wherein the pre-treatment process comprises an ion implantation process.

3. The patterning method of claim 2, wherein the first etching process comprises a plasma etching process.

4. The patterning method of claim 2, wherein an ion source of the ion implantation process comprises Ar, N₂, P or a combination thereof.

5. The patterning method of claim 2, wherein an energy of the ion implantation process is within a range of 5 to 60 keV.

6. The patterning method of claim 2, wherein a dosage of the ion implantation process is within a range of 1×10 ¹⁵/cm² to 5×10¹⁶/cm².

7. The patterning method of claim 2, wherein an inclination angle of the ion implantation process is within a range of 0 to 7 degrees.

8. The patterning method of claim 1, further comprising, before the pre-treatment process is performed, performing a second etching process with the patterned mask layer as a mask to remove a portion of the material layer exposed in the first opening.

9. The patterning method of claim 8, further comprising, after the first etching process is performed, performing a third etching process with the patterned mask layer as a mask to remove a portion of the material layer exposed in the second opening.

10. The patterning method of claim 9, further comprising, after the third etching process is performed, repeating the pre-treatment process and the first etching process.

11. The patterning method of claim 1, further comprising, after the first etching process is performed, performing another etching process with the patterned mask layer as a mask to remove a portion of the material layer exposed in the second opening.

12. The patterning method of claim 11, further comprising, after the another etching process is performed, repeating the pre-treatment process and the first etching process.

13. A patterning apparatus, comprising:
a multi-compartment chamber, comprising a first compartment and a second compartment at least;
an etching unit in the first compartment, for etching a material layer;
a modification unit in the second compartment, for modifying the material layer; and
a transfer unit arranged between the first compartment and the second compartment, for transferring the material layer between the first compartment and the second compartment.

14. The patterning method of claim 13, wherein the modification unit comprises an ion implantation machine.

15. The patterning method of claim 14, wherein the etching unit comprises a plasma etching machine.
